(19) United States
(12) Patent Application Publication
(10) Pub. No.: US 2016/0322410 A1
(43) Pub. Date: Nov. 3, 2016

(54) IMAGING DEVICE, AND SOLID-STATE IMAGE ELEMENT FOR USE THEREIN

(71) Applicant: Panasonic Intellectual Property Management Co., Ltd., Osaka (JP)

(72) Inventors: HIROKI YAMASHITA, Kanagawa (JP); TAKESHI KAWABATA, Osaka (JP); SATORU WAGA, Toyama (JP); HIDETO MOTOMURA, Kyoto (JP)

(21) Appl. No.: 15/206,271

(22) Filed: Jul. 10, 2016

Related U.S. Application Data
(63) Continuation of application No. PCT/JP2015/000148, filed on Jan. 15, 2015.

(30) Foreign Application Priority Data
Jan. 29, 2014 (JP) 2014-014969

(51) Int. Cl. H01L 27/146; G01N 1/36; H04N 5/225

(52) U.S. Cl. CPC H01L 27/14618; H01L 27/14683; H04N 5/2253; G01N 1/36

(57) ABSTRACT

An imaging device includes a solid-state image element and an encapsulation section. The solid-state image element has an imaging region. In the imaging region, the solid-state image element receives light which is transmitted through an imaging target placed on the imaging region. The encapsulation section is placed on a surface, on which the imaging region is formed, so as to enclose the imaging target. The solid-state image element is peelable from the encapsulation section to enable the solid-state image element to be reused.

### RELATED APPLICATIONS

This application is a Continuation of International Application No. PCT/JP2015/000148, filed on Jan. 15, 2015, which in turn claims priority from Japanese Patent Application No. 2014-014969, filed on Jan. 29, 2014, the contents of all of which are incorporated herein by reference in their entireties.

### BACKGROUND

1. Technical Field

The present disclosure relates to an imaging device and a solid-state image element for use therein.

2. Description of the Related Art

Pathological diagnosis for diagnosing disease from a tissue directly obtained from an affected area of a patient is quite effective to identify the name and condition of the disease. Photographing of microscopic images in hospitals or laboratories is performed to a large amount of specimens, and as a technique of photographing a large amount of microscopic images, a microscopic imaging device disclosed in Unexamined Japanese Patent Publication No. 2009-223164 has been proposed.

On the other hand, as illustrated in FIG. 15, the conventional art disclosed in Unexamined Japanese Patent Publication No. H06-311879 discloses a biosensor that includes solid-state image element 201, culture vessel 202 held on an imaging surface of solid-state image element 201, cell 203 stored in culture vessel 202, and medium 204 for growing cell 203.

### SUMMARY

An imaging device according to one aspect of the present disclosure includes a solid-state image element and an encapsulation section. The solid-state image element has an imaging region. In the imaging region, the solid-state image element receives light which is transmitted through an imaging target placed on the imaging region. The encapsulation section is disposed on a surface, on which the imaging region is formed, so as to enclose the imaging target. The solid-state image element is peelable from the encapsulation section to enable the solid-state image element to be reused.

A solid-state image element according to one aspect of the present disclosure is used for an imaging device including the solid-state image element and an encapsulation section. The solid-state image element has an imaging region, and receives light in the imaging region, the light being transmitted through an imaging target placed on the imaging region. The encapsulation section is disposed on a surface, on which the imaging region is formed, so as to enclose the imaging target. The solid-state image element is peelable from the encapsulation section to enable the solid-state image element to be reused.

An imaging device and a solid-state image element according to the present disclosure can implement high image performance at low cost.

### BRIEF DESCRIPTION OF THE DRAWINGS

FIG. 1A is a sectional structural view of an imaging device according to an exemplary embodiment;

FIG. 1B is a planar structural view of the imaging device according to the exemplary embodiment;

FIG. 2 is a sectional structural view of the imaging device according to the exemplary embodiment;

FIG. 3 is a sectional structural view of the imaging device according to the exemplary embodiment;

FIGS. 4A to 4E are views of manufacturing processes of the imaging device according to the exemplary embodiment;

FIGS. 5A to 5E are sectional views of manufacturing processes of the imaging device according to the exemplary embodiment;

FIG. 6A is a sectional structural view of an imaging device according to a first modification of the exemplary embodiment;

FIG. 6B is a planar structural view of the imaging device according to the first modification of the exemplary embodiment;

FIG. 7A is a sectional structural view of an imaging device according to the first modification of the exemplary embodiment;

FIG. 7B is a planar structural view of the imaging device according to the first modification of the exemplary embodiment;

FIG. 8A is a sectional structural view of an imaging device according to a second modification of the exemplary embodiment;

FIG. 8B is a planar structural view of the imaging device according to the second modification of the exemplary embodiment;

FIG. 9A is a sectional structural view of an imaging device according to a third modification of the exemplary embodiment;

FIG. 9B is a planar structural view of the imaging device according to the third modification of the exemplary embodiment;

FIG. 10A is a sectional structural view of an imaging device according to a fourth modification of the exemplary embodiment;

FIG. 10B is a planar structural view of the imaging device according to the fourth modification of the exemplary embodiment;

FIG. 11A is a sectional structural view of an imaging device according to the fourth modification of the exemplary embodiment;

FIG. 11B is a planar structural view of the imaging device according to the fourth modification of the exemplary embodiment;

FIG. 12A is a sectional structural view of an imaging device according to the fourth modification of the exemplary embodiment;

FIG. 12B is a planar structural view of the imaging device according to the fourth modification of the exemplary embodiment;

FIG. 13 is a sectional structural view of an imaging device according to the fourth modification of the exemplary embodiment;

FIG. 14 is a sectional structural view of an imaging device according to the fourth modification of the exemplary embodiment; and

FIG. 15 is a sectional structural view of a biosensor according to the conventional art.

### DETAILED DESCRIPTION OF EMBODIMENT

Firstly, the problem of the conventional art will be described. The conventional art disclosed in Unexamined Japanese Patent Publication No. 2009-223164 has a problem of difficulty in becoming popular, because it needs an expensive microscopic imaging device. On the other hand, the conventional art disclosed in Unexamined Japanese Patent Publication No. 1106-311879 has a problem of being unable to acquire a high-quality image due to the presence of the culture container and the medium.

In view of the above problems, the present disclosure provides an imaging device having high image performance at low cost and a solid-state image element for use therein.

An imaging device (specimen imaging device, electronic prepared slide) according to the exemplary embodiment of the present disclosure will be described below with reference to the drawings. Note that the exemplary embodiments described below illustrate only one specific example, and numerical values, shapes, materials, elements, arrangement position and connection manner of elements, steps, the order of steps, and the like are merely illustrative and do not intend to limit the present disclosure. It is to be noted that, in the present exemplary embodiment, the aspect in which a specimen (imaging target) placed on a slide glass (transparent substrate) is imaged with an electronic component (integrated circuit, semiconductor chip) such as a solid-state image element disposed on the specimen is referred to as an electronic prepared slide.

### Exemplary Embodiment

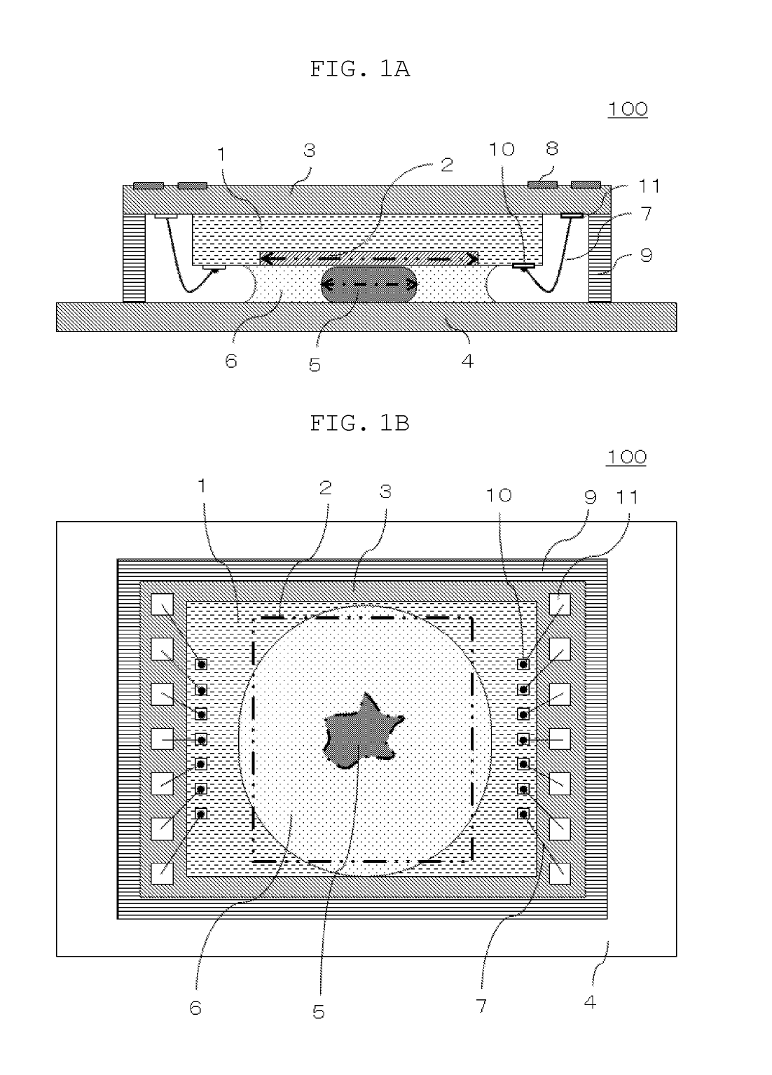

FIGS. 1A and 1B are each a sectional structural view and a planar structural view of an imaging device (specimen imaging device, electronic prepared slide) according to the exemplary embodiment. In the drawings, imaging target (specimen) (the imaging target and the specimen include a pathological specimen or blood) 5 and encapsulation section 6 are also illustrated for facilitating the description.

As illustrated in FIGS. 1A and 1B, imaging device 100 according to the present exemplary embodiment includes semiconductor chip (solid-state image element) 1, package substrate 3 disposed on the back surface of semiconductor chip 1, wires 7 that electrically connect semiconductor chip 1 and package substrate 3, transparent substrate (slide glass) 4 disposed to be opposite to semiconductor chip 1, and side wall 9 formed on the surface of package substrate 3 on which semiconductor chip 1 is disposed. Encapsulation section 6 is disposed between semiconductor chip 1 and transparent substrate 4 so as to enclose imaging target (specimen, pathological specimen, blood, etc.) 5.

It is to be noted that the wording “encapsulation” in the present disclosure does not strictly mean sealing. For example, the case in which a part of imaging target (specimen, pathological specimen, blood, etc.) 5 is exposed from encapsulation section 6 is included in the meaning of encapsulation in the present disclosure.

Encapsulation section 6 uses an encapsulating material (chemical material), and is formed to enclose imaging target 5. For example, a popular encapsulating material formed by dissolving acryl resin into xylene and having excellent curing characteristics is used as the encapsulating material.

However, the encapsulating material (chemical material) used for forming encapsulation section 6 is not limited to the above popular encapsulating material, and other chemical materials (liquid materials, gel materials) can be used. For example, in the case where priority is placed on the characteristic of reusing semiconductor chip 1 as described below, a chemical material used for the encapsulating material can be selected with priority being placed on peel property, and encapsulation section 6 can be formed by use of such chemical material.

Further, semiconductor chip 1 has imaging region 2 where incident light is received and the received light is converted into an electric signal. Imaging region 2 of semiconductor chip 1 is in contact with encapsulation section 6 or imaging target 5, so that an image with high resolution can be imaged (the contact between semiconductor chip 1 and encapsulation section 6 or imaging target 5 in this case is referred to as “in direct contact with each other”). However, the present exemplary embodiment aims to shorten the focal length between semiconductor chip 1 and imaging target 5, and it is not necessary that semiconductor chip 1 (imaging region 2) is in contact with encapsulation section 6 or imaging target 5. For example, a transparent film may be interposed between encapsulation section 6 (or encapsulation section 6 and imaging target 5) and semiconductor chip 1 (imaging region 2). This transparent film and encapsulation section 6 (or encapsulation section 6 and imaging target 5) may be in contact with each other. Additionally, this transparent film and semiconductor chip 1 may be in contact with each other (the contact between semiconductor chip 1 and encapsulation section 6 or imaging target 5 is referred to as “in indirect contact with each other”). With this configuration, the peeling between encapsulation section 6 (or encapsulation section 6 and imaging target 5) and semiconductor chip 1 is facilitated, whereby reusing of semiconductor chip 1 is facilitated. Notably, in the present disclosure, the meaning of “imaging target disposed on the imaging region” includes both the case where imaging region 2 and imaging target 5 are in direct contact with each other and the case where they are in indirect contact with each other as described above.

Semiconductor chip 1 includes a circuit (for example, a signal output circuit, a noise cancel circuit, a signal conversion circuit such as AD converter, and signal amplification circuit) on a semiconductor substrate such as silicon. One example of the circuit is a solid-state image element (image sensor).

For example, imaging region 2 is an area where light-receiving units (for example, photodiode) are disposed on the semiconductor substrate in a matrix. In imaging region 2, incident light is received, and is converted into an electric signal. Wiring lines (not illustrated) for transmitting an output signal are connected to imaging region 2 and first electrode pads 10. Imaging region 2 performs imaging of imaging target 5 with the electric signal from first electrode pads 10.

Further, in the case where semiconductor chip 1 is a CCD (Charge-Coupled Device) image sensor, a transfer electrode (transfer channel) for reading charges generated from the light-receiving units and transferring the read charges, and the like are disposed on imaging region 2 in addition to photodiodes (light-receiving units).

On the other hand, in the case where semiconductor chip 1 is a CMOS (Complementary Metal-Oxide-Semiconductor) image sensor, a transfer transistor that transfers signal charges obtained through photoelectric conversion at the light-receiving units to a floating diffusion (FD) unit, a reset transistor that controls potential Vfd of the FD unit, an amplification transistor that outputs a signal according to potential Vfd of the FD unit to column signal lines, and the like are disposed on imaging region 2 in addition to the photodiodes (light-receiving units).

However, the configuration of imaging region 2 is not limited to the above configuration (for example, in the case of a CMOS image sensor, a selection transistor for pixel selection may further be provided). In addition, the solid-state image element is not limited to those described above. Other solid-state image elements (for example, an image sensor provided with a photoelectric conversion film formed from an organic material or an inorganic material on a semiconductor substrate, in place of a photodiode provided on a semiconductor substrate, for trapping light and performing photoelectric conversion) may be used.

In addition, it is more preferable that a surface treatment for enhancing at least one of hydrophilic property, hydrophobic property, lipophilic property, lipophobic property, and peel property is performed to the surface of semiconductor chip 1 in imaging region 2 in imaging device 100. For example, with the surface treatment for enhancing lipophilic property of the surface of semiconductor chip 1 in imaging region 2, the generation of voids (bubbles) between semiconductor chip 1 and transparent substrate 4 can be prevented during the formation of encapsulation section 6 by pushing out the encapsulating material.

However, in the present disclosure, the treatment on the surface of semiconductor chip 1 in imaging region 2 (surface treatment) is not limited to prevent the generation of voids (bubbles) between semiconductor chip 1 and transparent substrate 4. The surface treatment may be performed for the purpose of enhancing other properties. For example, in the case where priority is placed on the characteristic of reusing semiconductor chip 1 as described above, a surface treatment in consideration of peel property with respect to encapsulation section 6 and/or the above-described transparent film can be performed.

As one example of the surface treatment for imaging region 2 of semiconductor chip 1, a plasma treatment (surface plasma treatment), or treatments such as application, injection, or spraying of chemicals can be performed to a protection film that is the uppermost layer of semiconductor chip 1.

In imaging device 100 according to the present exemplary embodiment, the distance between imaging region 2 and imaging target 5 is short, that is, the focal length is short. Therefore, a microlens which is popularly used is not necessarily provided on the surface of semiconductor chip 1. However, if priority is placed on sensitivity characteristic (that is, brightness of an image) of imaging device 100, a microlens is preferably provided.

On the other hand, in the case where priority is placed on enhancing image characteristics concerning smear or color mixture by allowing incident light to reach imaging region 2 perpendicularly (in other words, by reducing a component of oblique light), a structure without having a microlens is preferable. With the configuration in which imaging region 2 of semiconductor chip 1 and imaging target 5 are provided to be close to each other without mounting a microlens, the distance between imaging region 2 and imaging target 5 can further be reduced, whereby an image having higher resolution can be obtained. Further, the process of forming a microlens can be eliminated, so that the manufacturing cost of semiconductor chip 1 can be reduced.

Package substrate 3 is disposed on the back surface of semiconductor chip 1. Semiconductor chip 1 is fixed on package substrate 3 with dice bonding. Second electrode pads 11 electrically connected to semiconductor chip 1 are provided on the surface of package substrate 3 on which semiconductor chip 1 is fixed. The back surface of package substrate 3 is provided with external output terminals 8 which can be electrically connected to the outside of imaging device 100. Notably, an image signal or the like input to second electrode pads 11 from semiconductor chip 1 is transmitted to the outside through external output terminals 8 electrically connected to second electrode pads 11.

External output terminals 8 may have a shape of ball, bump, or land. However, the shape is not limited thereto. Through the selection of external output terminals 8 described above, the connection with pins 15 of socket 14 described below is facilitated. Further, external output terminals 8 can be disposed on the back surface in a grid, whereby multiple pins can be used. For example, in the case where about 40 mm square package substrate 3 is used, and external output terminals 8 are disposed with a pitch of about 1 mm, more than 1000 pins can be disposed.

For example, a ceramic or organic material can be used for the material of package substrate 3. When ceramic is used, the difference in thermal expansion between package substrate 3 and semiconductor chip 1 due to temperature change can be suppressed, whereby reliability can be enhanced. When an organic material is used, package substrate 3 can be manufactured with low cost. Wires 7 electrically connect first electrode pads 10 formed on semiconductor chip 1 and second electrode pads 11 formed on package substrate 3 to each other.

Here, wire bonding for electrically connecting semiconductor chip 1 and package substrate 3 will be described below in detail with reference to the drawings.

FIGS. 1A and 1B illustrate a normal bonding technique in which ball bonding is used for semiconductor chip 1 and stitch bonding is used for package substrate 3. The loop height of wire bonding is affected by a wire length and the difference in height between a first bonding pad and a second bonding pad. However, when the wire length is about 1 mm, and the difference in height between bonding points is about 200 μm, low loop bonding of about 100 μm from the first bonding pad can be implemented due to the enhancement in loop control of imaging device 100 and development of wire bonding.

However, it is considered that, in imaging device 100, the thickness of semiconductor chip 1 is set to be not less than 300 μm to prevent distortion of semiconductor chip 1, and with this, the difference in height of bonding points becomes larger.

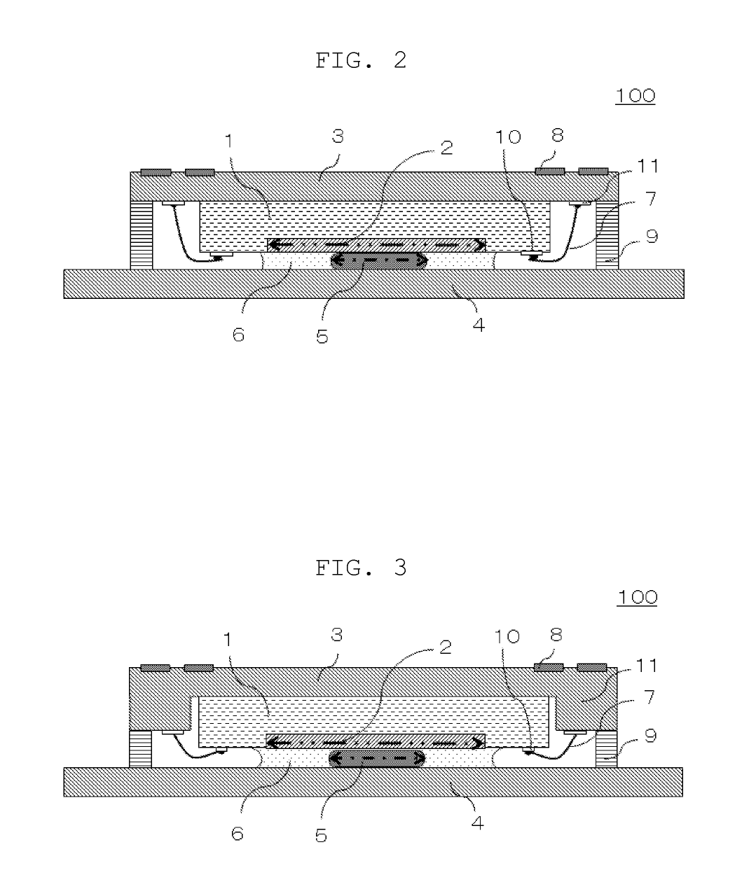

In view of this, as illustrated in FIG. 2, a stud bump is preliminarily formed on first electrode pad 10 on semiconductor chip 1, wherein ball bonding is used for package substrate 3 and stitch bonding is used for semiconductor chip 1. With the use of such bonding method, the loop height of wire 7 can be reduced to about 100 μm, and the distance between imaging region 2 and imaging target 5 can be reduced. Thus, clearer image data can be acquired.

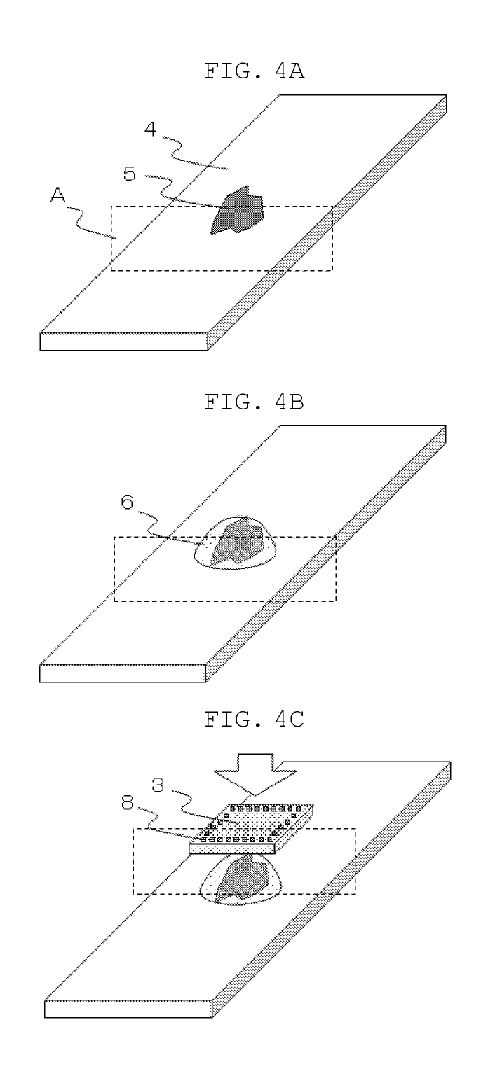

Further, as illustrated in FIG. 3, the height of second electrode pad 11 on package substrate 3 is set larger than the bonding portion between semiconductor chip 1 and package substrate 3 toward semiconductor chip 1. With this, the difference in height between the first bonding and the second bonding can be reduced, so that the loop height of wire 7 can be reduced, and the distance between imaging region 2 and imaging target 5 can be reduced. Thus, clearer image data can be acquired.

The detail of imaging device (specimen imaging device, electronic prepared slide) will be continuously described with reference to FIGS. 1A and 1B. Transparent substrate 4 is disposed to face semiconductor chip 1. For example, transparent substrate 4 is a slide glass having long sides of about 76 mm, short sides of about 26 mm, and thickness from 0.9 mm to 1.2 mm inclusive.

The distance between semiconductor chip 1 and transparent substrate 4 can be held constant through the contact between transparent substrate 4 and side wall 9 formed on the surface of package substrate 3 on which semiconductor chip 1 is disposed. On the other hand, transparent substrate 4 is not necessarily in contact with side wall 9. Transparent substrate 4 may be fixed by imaging region 2 and encapsulation section 6. When transparent substrate 4 and side wall 9 are not in contact with each other as described above, gas generated during curing of encapsulating material used as the material of encapsulation section 6 can be released. Further, imaging region 2 is entirely bonded to transparent substrate 4, so that they can be fixedly bonded to each other. Since transparent substrate 4 is sufficiently larger than semiconductor chip 1, an operator can grip transparent substrate 4. Therefore, imaging device 100 is easy to handle.

Further, as illustrated in FIGS. 1A and 1B, side wall 9 is formed on the surface of package substrate 3 on which semiconductor chip 1 is disposed. For example, a ceramic or resin can be used for the material of side wall 9. When ceramic which is the same as the material of package substrate 3 is used, the difference in thermal expansion between package substrate 3 and side wall 9 due to temperature change can be suppressed, whereby reliability can be enhanced. On the other hand, when resin is used, the manufacture at low cost is enabled.

Transparent substrate 4 and side wall 9 are in contact with each other in FIG. 1A. However, the total of the thickness of semiconductor chip 1 and the thickness of imaging target 5 is larger than the height of side wall 9, they are not in contact with each other, but side wall 9 is suspended. When side wall 9 and transparent substrate 4 are not in contact with each other, the gap between them may be filled with filling resin (not illustrated). However, in the case where the gap is filled with filling resin, the filling resin is filled after encapsulation section 6 is cured, since a large amount of gas is generated during curing of the encapsulating material used as the material of encapsulation section 6.

With the configuration described above, wires 7 and encapsulation section 6 are not exposed to the outside air, whereby deterioration due to moisture or foreign matters can be prevented. Thus, reliability is enhanced. In FIG. 1A, side wall 9 is formed on four sides of package substrate 3. However, it is not necessarily formed on four sides. When a part of side wall 9 is eliminated, gas generated from encapsulation section 6 can be released, whereby voids are difficult to be generated.

Imaging target 5 is enclosed by encapsulation section 6 between semiconductor chip 1 and transparent substrate 4 so as not to be exposed to the outside air. One example of imaging target 5 is a histopathological slice having a size from 5 mm to 20 mm inclusive and thickness of about several micrometers.

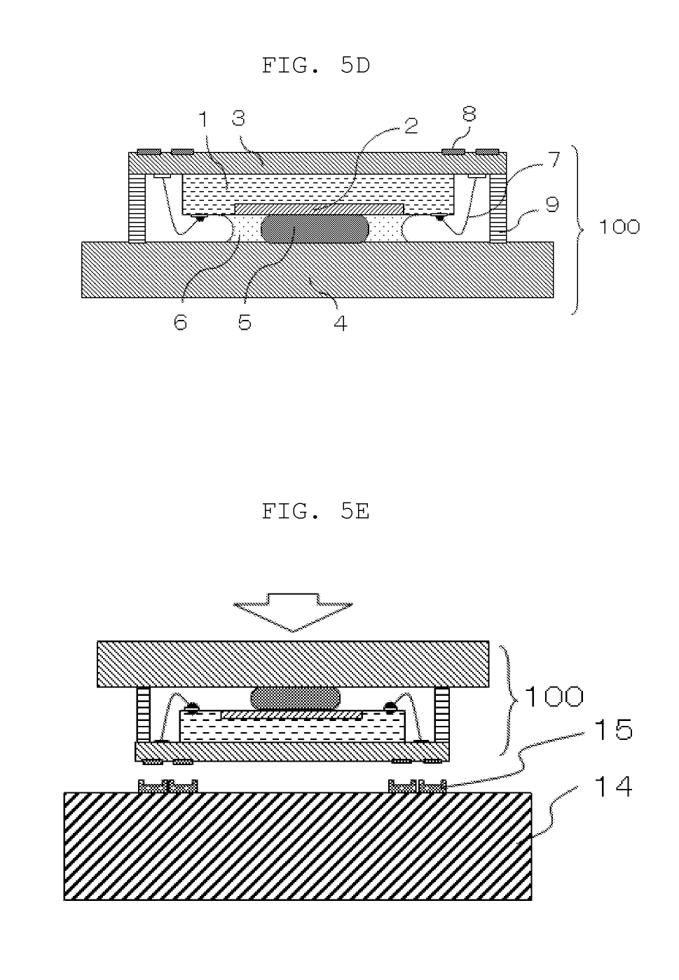

Further, imaging device 100 is characterized in that, as illustrated in FIGS. 1A and 1B (and FIGS. 6A to 12A and 6B to 12B described later), the area of imaging region 2 (the area of the region indicated by two-dot-chain line in the drawings) is larger than the area of imaging target 5 (the area of the region indicated by a one-dot-chain line in the drawings) in the direction parallel to the surface of transparent substrate 4 facing semiconductor chip 1. Moreover, as illustrated in FIG. 1B, imaging device 100 is characterized in that imaging target 5 (the region indicated by a one-dot-chain line in the drawings) is entirely covered by imaging region 2 (the region indicated by two-dot-chain line in the drawings).

Thus, imaging device 100 is capable of imaging the entire region of imaging target 5 at a time. In other words, the entire region of imaging target 5 can be imaged at a time without a need to move a slide glass (or a stage of a microscope on which the slide glass is placed) as in the case where an observation target is observed with a general microscope. Further, it is also unnecessary to perform focusing every observation of imaging target 5, whereby a load of an operator can significantly be reduced (notably, in the case where an operator desires to enlarge an image, he/she can enlarge the image using an electronic zoom function of the solid-state image element or a zoom process of image data (electronic data) obtained by imaging the entire region).

In addition, imaging device 100 does not need a wide-angle lens (optical lens) used for a popular camera, whereby downsizing of imaging device 100 can be implemented.

Further, with the areas and positional relationship of imaging region 2 and imaging target 5 as described above, extremely high precise positioning is unnecessary for combining transparent substrate 4 and semiconductor chip 1 together.

Subsequently, an imaging method using the imaging device (specimen imaging device, electronic prepared slide) according to the exemplary embodiment will be described below with reference to the drawings.

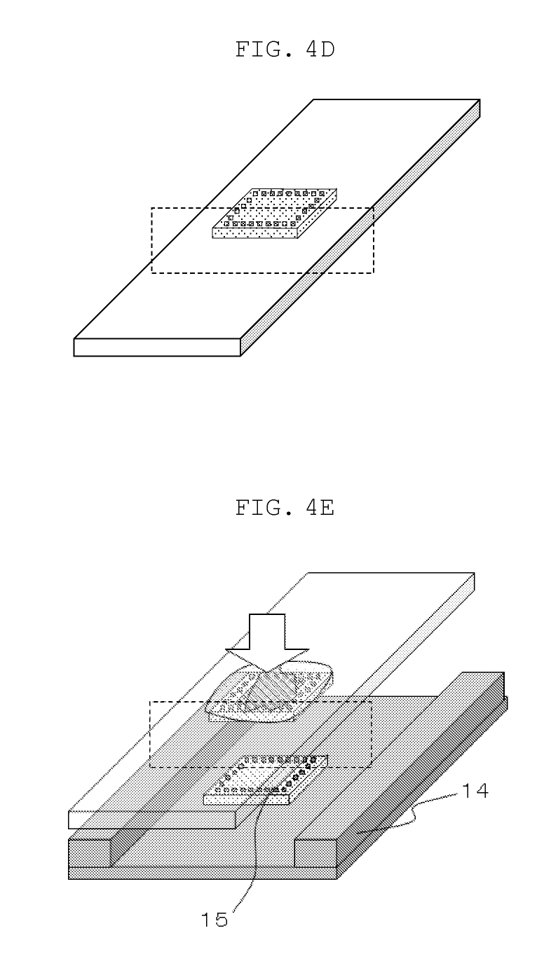

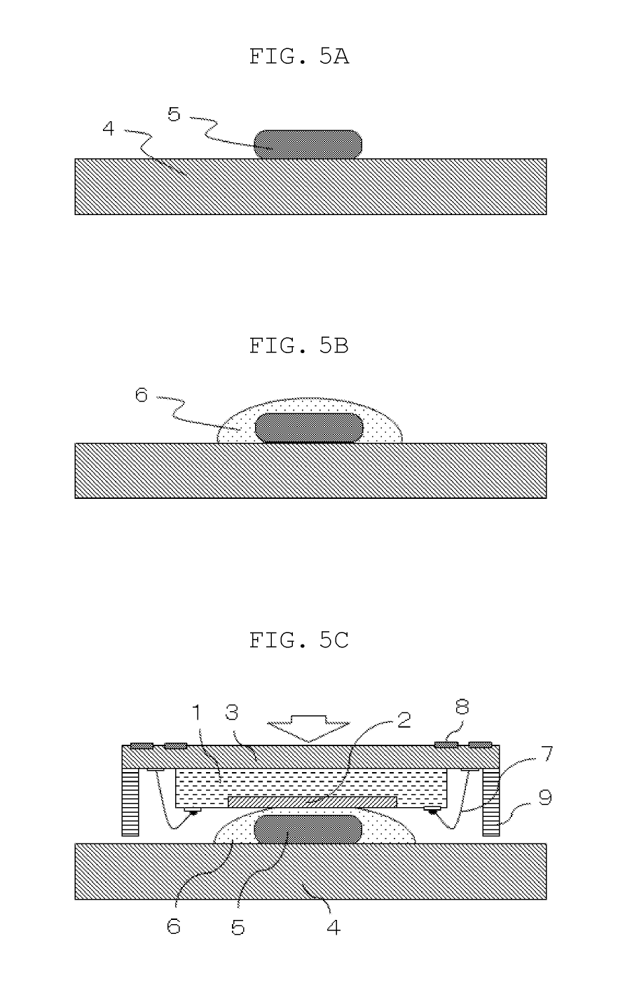

FIGS. 4A to 4E are views illustrating processes of the imaging method with the imaging device according to the present exemplary embodiment, and FIGS. 5A to 5E are sectional views of imaging steps corresponding to A plane in FIGS. 4A to 4E. In the drawings, imaging target 5 and encapsulation section 6 are also illustrated for facilitating the description.

Firstly, a pretreatment is performed to imaging target 5 as illustrated in FIGS. 4A and 5A. For example, obtained imaging target 5 is dehydrated and embedded in paraffin. Thereafter, the resultant is sliced with a desired thickness of about a few micrometers to about tens of micrometers on transparent substrate 4, the paraffin is removed, and processes such as dyeing are performed.

Then, an encapsulating material is applied on imaging target 5 as illustrated in FIGS. 4B and 5B.

Next, as illustrated in FIGS. 4C and 5C, semiconductor chip 1, which is die-bonded on package substrate 3 and has second electrode pads 11 connected to first electrode pads 10 with wires 7, is disposed above imaging target 5 and the encapsulating material. At that time, imaging region 2 of semiconductor chip 1 is positioned so as to be located above imaging target 5. At that time, an operator adjusts semiconductor chip 1 such that imaging region 2 covers the entire of imaging target 5 with visual observation from the glass as appropriate.

Then, as illustrated in FIGS. 4D and 5D, semiconductor chip 1 is pressed against transparent substrate 4 to bring semiconductor chip 1 and imaging target 5 or side wall 9 and transparent substrate 4 to be in contact with each other, while the encapsulating material on imaging target 5 is pushed out. With this, imaging target 5 is encapsulated by semiconductor chip 1, encapsulation section 6, and transparent substrate 4. Further, encapsulation section 6 is formed with this step.

Finally, as illustrated in FIGS. 4E and 5E, external output terminals 8 of imaging device 100 are inserted into pins 15 of socket 14. Thus, the image signal from imaging device 100 can externally be output to a pathological examination system (digitizer).

As described above, imaging device 100 according to the present exemplary embodiment described with reference to the drawings can output an image signal (electronic signal) therefrom without using an expensive microscopic imaging device, thereby being capable of significantly reducing cost (examination cost) required for observation. That is, imaging device 100 according to the present exemplary embodiment is capable of widely diffusing advanced pathological diagnosis.

According to imaging device 100 in the present exemplary embodiment described with reference to the drawings, the distance between imaging target 5 and imaging region 2 can be reduced, whereby an image with high resolution can be obtained.

Further, morphological information of imaging target 5 read by semiconductor chip 1 is output to an image processing apparatus or memory device using external terminals, and also, a signal input to semiconductor chip 1 is needed. Imaging device 100 according to the present exemplary embodiment can ensure external terminals for the output and input described above, and further can be configured with a desired size.

Since imaging target 5 is isolated from the outside air by encapsulation section 6 between transparent substrate 4 and semiconductor chip 1, deterioration of imaging target 5 can be prevented. Specifically, using imaging device 100 according to the present exemplary embodiment prevents imaging target 5 from being exposed to the outside air without being encapsulated, and being deteriorated by an effect of external environment. Thus, accurate measurement is enabled, and further, even in the reexamination after a long-term storage, accurate measurement is also enabled.

In addition, since the external terminals of semiconductor chip 1 are extracted on the surface opposite to imaging target 5, increase in the number of terminals due to advanced function (increase in resolution) of the solid-state image element and downsizing can easily be attained, and further, the extraction of external terminals from semiconductor chip 1 is easy.

### First Modification of Exemplary Embodiment

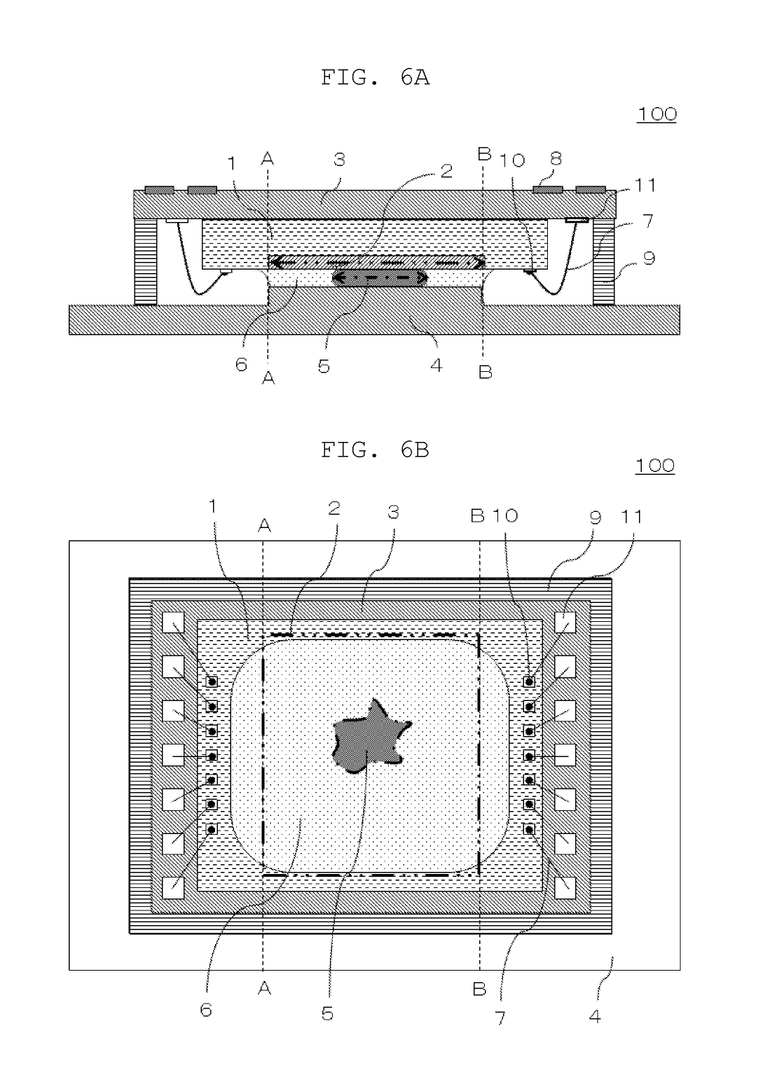

FIGS. 6A, 6B, 7A, and 7B are structural views illustrating an imaging device (specimen imaging device, electronic prepared slide) according to a first modification of the exemplary embodiment, wherein FIGS. 6A and 7A are sectional structural views, and FIGS. 6B and 7B are planar structural views.

As illustrated in FIG. 6A, transparent substrate 4 has a step, and a region of transparent substrate 4 corresponding to imaging region 2 projects at a level equal to or larger than the loop height of wire 7. In other words, the part between A and B of transparent substrate 4 has a projecting shape as illustrated in FIG. 6A. Further, as illustrated in FIG. 6B, the side ends of the projecting part of transparent substrate 4 are parallel to the arraying direction of wires 7 (the arraying direction of first electrode pads 10 or second electrode pads 11).

Alternatively, as illustrated in FIG. 7A, transparent substrate 4 has a structure in which a part thereof at the outside of side wall 9 projects, as well as the structure illustrated in FIG. 6A. Specifically, transparent substrate 4 is configured such that a step (groove, recess) is formed thereon to allow the region opposite to imaging region 2 to project at a level equal to or larger than the loop height of wire 7, and the part at the outside of side wall 9 also projects. Specifically, as illustrated in FIG. 7A, the part between C and A of transparent substrate 4 and the part between B and D of transparent substrate 4 become a groove (recess), respectively. Further, as illustrated in FIG. 7B, the side ends of the projecting part of transparent substrate 4 are parallel to the arraying direction of wires 7 (the arraying direction of first electrode pads 10 or second electrode pads 11).

With the configuration illustrated in FIGS. 6A, 6B, 7A, and 7B, imaging target 5 can precisely be placed on transparent substrate 4 by using the step or groove as a mark. Further, this configuration can reduce the distance between imaging region 2 and imaging target 5, while preventing the contact between wires 7 and transparent substrate 4, whereby clearer image data can be obtained. In addition, semiconductor chip 1 and transparent substrate 4 can be bonded to each other with high precision by using the step or groove as a mark.

### Second Modification of Exemplary Embodiment

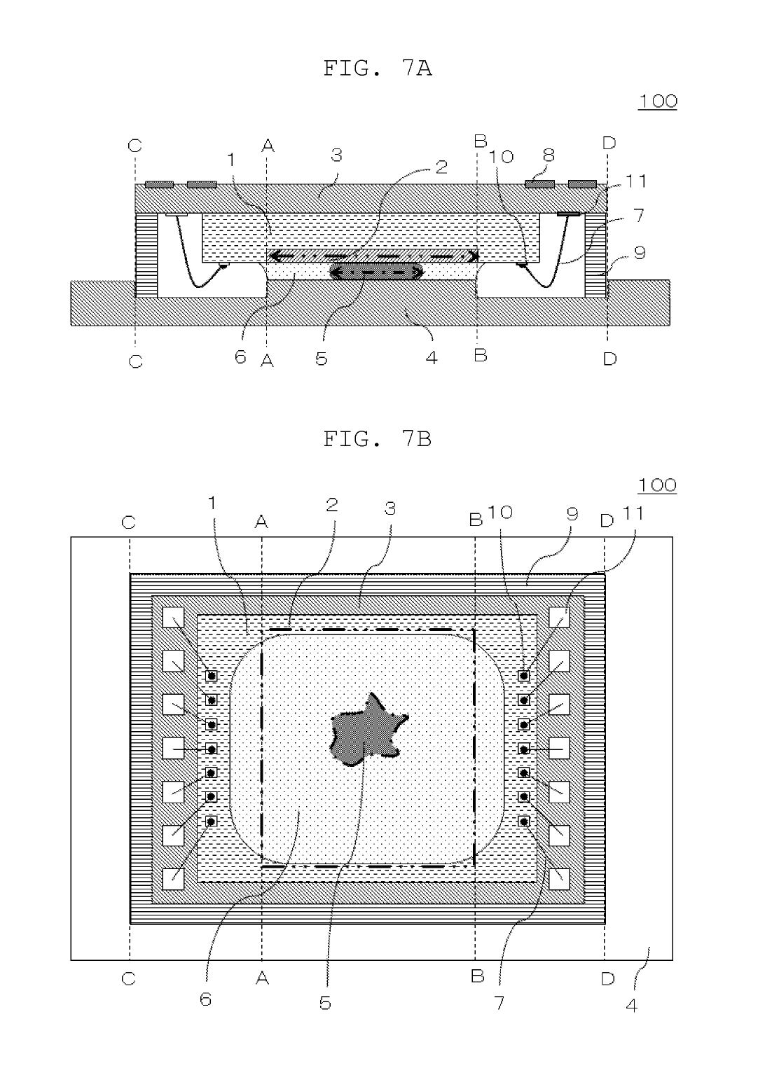

FIGS. 8A and 8B are each a sectional structural view and a planar structural view of an imaging device (specimen imaging device, electronic prepared slide) according to a second modification of the exemplary embodiment.

When semiconductor chip 1 is formed to be larger than transparent substrate 4 as illustrated in FIGS. 8A and 8B, side wall 9 supporting transparent substrate 4 is not needed, and transparent substrate 4 is disposed to avoid wires 7. This configuration eliminates the need to consider the contact between transparent substrate 4 and wires 7, and enables reduction in the distance between imaging region 2 and a specimen. Thus, clearer image data can be obtained.

### Third Modification of Exemplary Embodiment

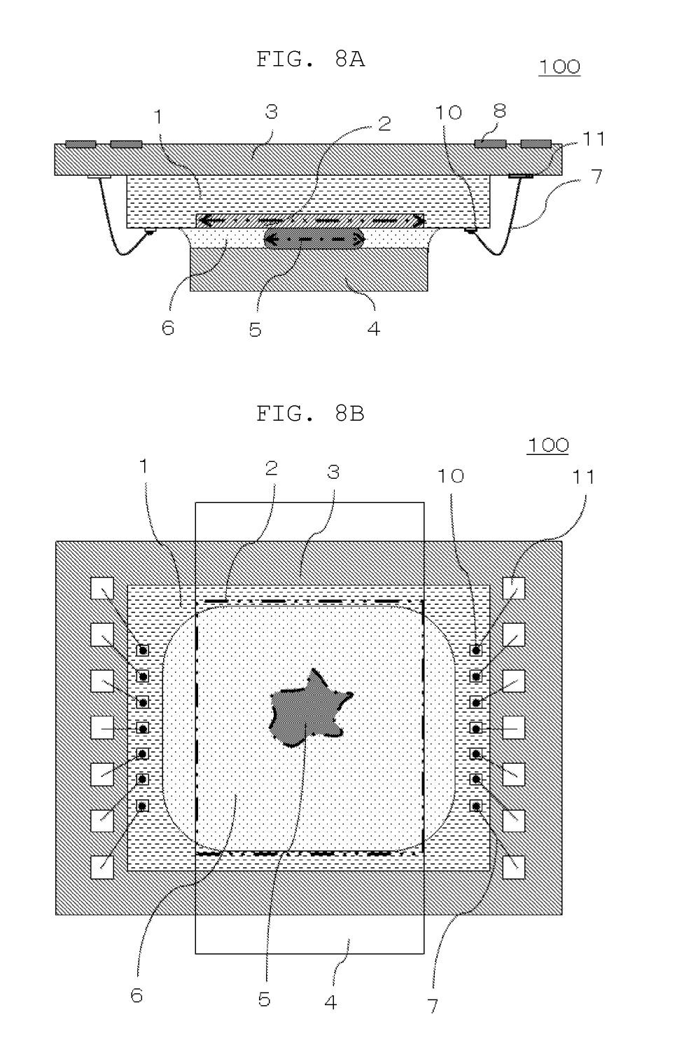

FIGS. 9A and 9B are each a sectional structural view and a planar structural view of an imaging device (specimen imaging device, electronic prepared slide) according to a third modification of the exemplary embodiment.

As illustrated in FIGS. 9A and 9B, dams 13 are formed between imaging region 2 and first electrode pads 10 on the surface of semiconductor chip 1. For example, dams 13 are formed by copper plating or gold plating with a semiconductor rewiring process. This configuration can prevent the contact between encapsulation section 6 and wires 7, and further prevent short-circuiting of wires 7 which are caused because wires 7 are taken away by encapsulation section 6.

Notably, FIG. 9A illustrates that dams 13 are in contact with transparent substrate 4. However, in the present exemplary embodiment, it is only necessary that dams 13 can prevent encapsulation section 6 from flowing over first electrode pads 10. Therefore, dams 13 are not necessarily in contact with transparent substrate 4.

Further, as illustrated in FIG. 9B, dams 13 are open in the arraying direction of wires 7 (the arraying direction of first electrode pads 10 or second electrode pads 11), and the encapsulating material can be flown into the part where wires 7 are not present.

### Fourth Modification of Exemplary Embodiment

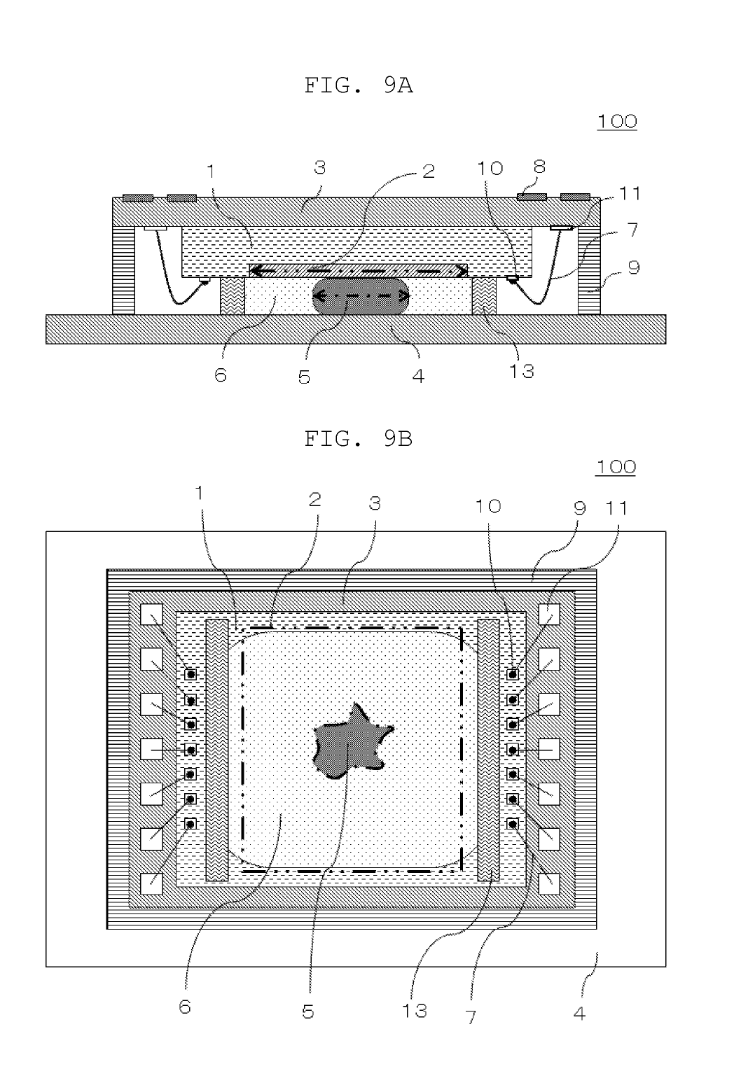

FIGS. 10A, 11A, 12A, 13, 14, 10B, 11B, and 12B are structural views illustrating an imaging device (specimen imaging device, electronic prepared slide) according to a fourth modification of the exemplary embodiment, wherein FIGS. 10A, 11A, 12A, 13, and 14 are sectional structural views, and FIGS. 10B, 11B, and 12B are planar structural views.

As illustrated in FIGS. 10A and 10B, imaging device 100 includes semiconductor chip 1, package substrate 3 disposed on the back surface of semiconductor chip 1, wires 7 that electrically connect semiconductor chip 1 and package substrate 3, transparent substrate 4 disposed to be opposite to semiconductor chip 1, encapsulation resin section 12 formed on package substrate 3 for encapsulating wires 7, and imaging target 5 encapsulated between semiconductor chip 1 and transparent substrate 4 by encapsulation section 6.

In imaging device 100 illustrated in FIGS. 10A and 10B, encapsulation resin section 12 for encapsulating wires 7 is formed on package substrate 3. With this configuration, wires 7 can be protected, and the space between transparent substrate 4 and semiconductor chip 1 can be kept constant. Further, encapsulation resin section 12 is not formed in the direction parallel to the arraying direction of wires 7 (the arraying direction of first electrode pads 10 or second electrode pads 11), and is open to the atmosphere. Therefore, gas generated during curing of an encapsulating material used as the material of encapsulation section 6 can be released, and the generation of voids can be prevented.

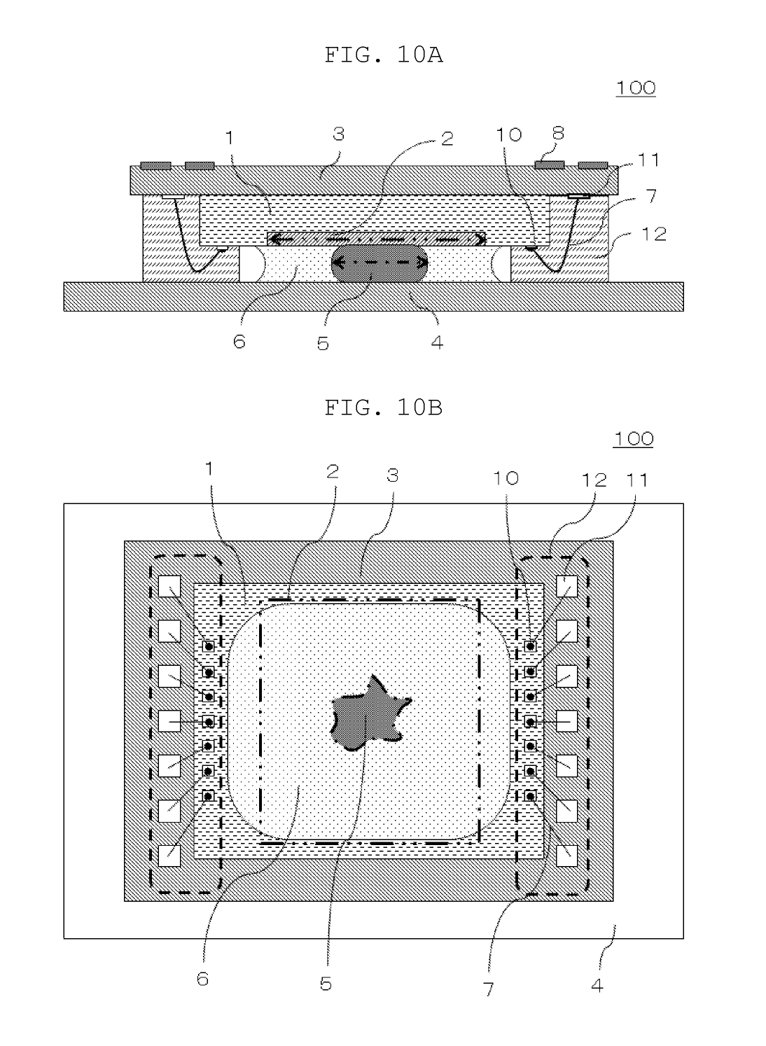

Notably, as illustrated in FIGS. 11A and 11B, transparent substrate 4 can be configured such that a step is formed thereon, and a region of transparent substrate 4 corresponding to imaging region 2 projects at a level equal to or larger than the loop height of wire 7. In other words, the part between A and B of transparent substrate 4 has a projecting shape as illustrated in FIG. 11A. That is, in imaging device 100 according to the fourth modification of the present exemplary embodiment, transparent substrate 4 may be processed such that the region of transparent substrate 4 facing imaging region 2 projects at a level equal to or larger than the loop height of wire 7. Further, as illustrated in FIG. 11B, the side ends of the projecting part of transparent substrate 4 are parallel to the arraying direction of wires 7 (the arraying direction of first electrode pads 10 or second electrode pads 11). This configuration eliminates the need to consider the contact between transparent substrate 4 and wires 7, and enables reduction in the distance between imaging region 2 and imaging target 5. Thus, clearer image data can be obtained.

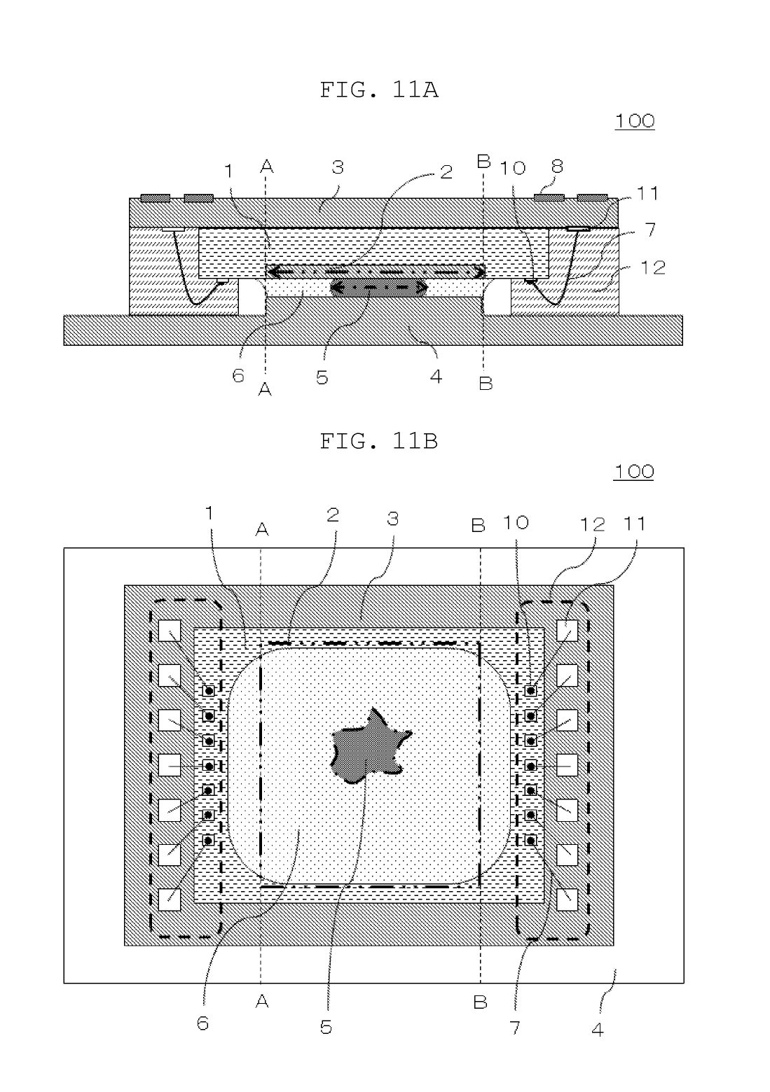

Further, as illustrated in FIGS. 12A and 12B, in imaging device 100 according to the fourth modification of the present exemplary embodiment, transparent substrate 4 is configured such that a step (groove, recess) is formed thereon to allow the region facing imaging region 2 of transparent substrate 4 to project at a level equal to or larger than the loop height of wire 7, and a part at the outside of side wall 9 also projects. Specifically, as illustrated in FIG. 12A, the part between C and A of transparent substrate 4 and the part between B and D of transparent substrate 4 become a groove (recess). That is, transparent substrate 4 may be processed such that the region of transparent substrate 4 facing imaging region 2 projects at a level equal to or larger than the loop height of wire 7 and the region outside encapsulation resin section 12 also projects. With this configuration, positioning in bonding semiconductor chip 1 and transparent substrate 4 to each other is facilitated, and imaging device 100 having excellent image performance and compact performance can be implemented at low cost. Notably, as illustrated in FIG. 12B, the side ends of the projecting part of transparent substrate 4 are parallel to the arraying direction of wires 7 (the arraying direction of first electrode pads 10 or second electrode pads 11).

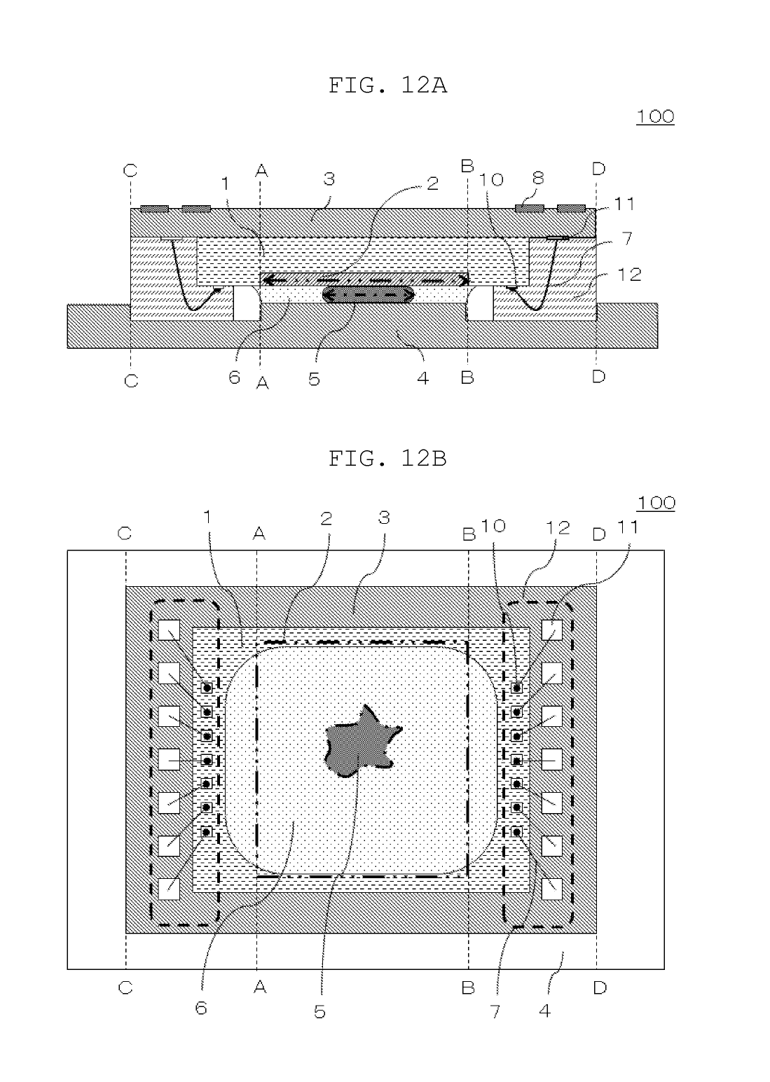

As illustrated in FIG. 13, in imaging device 100 according to the fourth modification of the present exemplary embodiment, encapsulation resin section 12 and transparent substrate 4 are not necessarily in contact with each other. According to the configuration illustrated in FIG. 13, imaging device 100 that does not need high precision in forming resin and has excellent image performance and compact performance can be implemented at low cost.

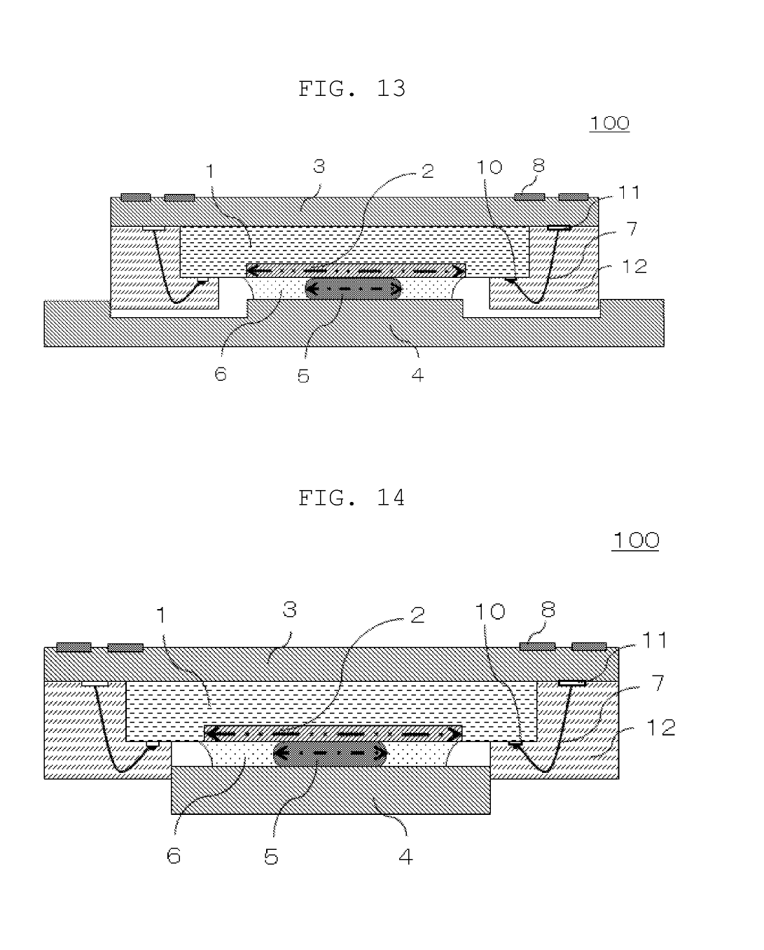

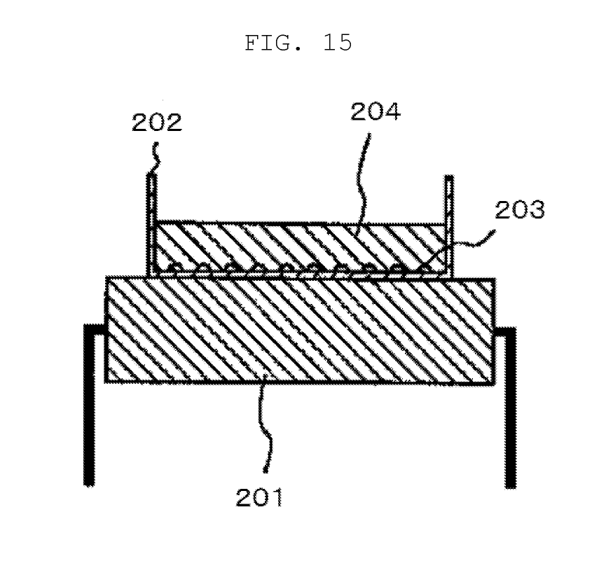

In addition, in the case where semiconductor chip 1 is larger than transparent substrate 4 in imaging device (specimen imaging device, electronic prepared slide) according to the fourth modification of the present exemplary embodiment as illustrated in FIG. 14, encapsulation resin section 12 is formed according to the size of transparent substrate 4, by which encapsulation resin section 12 functions as a guide. Thus, the positioning between imaging region 2 and imaging target 5 is facilitated, and imaging device 100 having excellent image performance and compact performance can be implemented at low cost.

Note that the imaging device, electronic prepared slide, and solid-state image element according to the present disclosure are not limited to exemplary embodiments described above. The present disclosure includes another embodiment carried out by combining optional elements in each exemplary embodiment, modifications obtained by performing various modifications, which have been conceived of by a person skilled in the art within a range not departing from the spirit of the present disclosure, to each exemplary embodiment, and various devices which incorporate the imaging device according to the present exemplary embodiment.

The imaging device, electronic prepared slide, and solid-state image element according to the present disclosure can implement high-quality imaging with low cost. Thus, they are useful for an examination of a pathological specimen, for example.

What is claimed is:

1. An imaging device comprising:
a solid-state image element that has an imaging region and receives light in the imaging region, the light being transmitted through an imaging target placed on the imaging region; and
an encapsulation section that is disposed on a surface, on which the imaging region is formed, so as to enclose the imaging target,
wherein the solid-state image element is peelable from the encapsulation section to enable the solid-state image element to be reused.

2. The imaging device according to claim 1, wherein
a material composing the encapsulation section is a liquid material or a gel material, and
the material has a peel property with respect to the solid-state image element.

3. The imaging device according to claim 1, further comprising a transparent film, wherein the encapsulation section is peeled from the solid-state image element with the transparent film.

4. The imaging device according to claim 1, wherein the imaging region has a surface to which a surface treatment for enhancing at least one of hydrophilic property, hydrophobic property, lipophilic property, lipophobic property, and peel property is performed.

5. The imaging device according to claim 4, wherein the surface treatment is a plasma treatment to a protection film that is an uppermost layer in the imaging region.

6. The imaging device according to claim 1, wherein the imaging region has an area larger than an area of the imaging target.

7. The imaging device according to claim 1,
wherein the solid-state image element has a first electrode, and
the imaging device comprises:
a package substrate having a second electrode; and
an electric connection section that electrically connects the first electrode and the second electrode to each other.

8. The imaging device according to claim 7, further comprising a side wall formed on a surface of the package substrate, the solid-state image element being disposed on the surface of the package substrate.

9. The imaging device according to claim 7, wherein the package substrate is an organic substrate or a ceramic substrate.

10. A solid-state image element for use in an imaging device which includes: the solid-state image element that has an imaging region and receives light in the imaging region, the light being transmitted through an imaging target placed on the imaging region; and an encapsulation section that is disposed on a surface, on which the imaging region is formed, so as to enclose the imaging target,
the solid-state image element being peelable from the encapsulation section to enable the solid-state image element to be reused.

11. The solid-state image element according to claim 10, wherein the imaging region has a surface to which a surface treatment for enhancing at least one of hydrophilic property, hydrophobic property, lipophilic property, lipophobic property, and peel property is performed.

12. The solid-state image element according to claim 11, wherein the surface treatment is a plasma treatment to a protection film that is an uppermost layer in the imaging region.

13. The solid-state image element according to claim 10, wherein the solid-state image element is a CCD image sensor, a CMOS image sensor, or an image sensor having a photoelectric conversion film.
